(19) United States
(12) Patent Application Publication
(10) Pub. No.: US 2007/0195578 A1
(43) Pub. Date: Aug. 23, 2007

(54) Semiconductor memory device

(76) Inventors: Yasuo Murakuki, Kyoto (JP); Takashi Miki, Hyogo (JP)

Correspondence Address: MCDERMOTT WILL & EMERY LLP, 600 13TH STREET, NW, WASHINGTON, DC, 20005-3096, US

(21) Appl. No.: 11/707,157

(22) Filed: Feb. 16, 2007

(30) Foreign Application Priority Data
Feb. 17, 2006 (JP) 2006-040757

(51) Int. Cl. G11C 11/22

(52) U.S. Cl. 365/145

(57) ABSTRACT

A memory cell array is composed of a plurality of memory cells arranged in a matrix. Each of the memory cells includes: a capacitor having a plate electrode connected to a common cell plate and a storage electrode; and a transistor provided between the storage electrode of the capacitor and a bit line, with a gate connected to a word line. A first amplifier amplifies an I/O line pair to a first voltage and a second voltage higher than the first voltage. A second amplifier amplifies a bit line pair to the first voltage and a third voltage higher than the second voltage. A switch element switches the connection relationship between the I/O line pair and the bit line pair among a connected state, a disconnected state and a transmission limited state in which the potential transmitted is limited.

### CROSS-REFERENCE TO RELATED APPLICATIONS

This application claims priority under 35 U.S.C. §119 on Patent Application No. 2006-40757 filed in Japan on Feb. 17, 2006, the entire contents of which are hereby incorporated by reference.

### BACKGROUND OF THE INVENTION

1. Field of the Invention

The present invention relates to a semiconductor memory device, and more particularly, to a technology effective when applied to a ferroelectric-embedded semiconductor memory device, in particular.

2. Description of Related Art

In recent years, there is known a semiconductor memory device that uses a ferro-electric film as the insulating film of a capacitor to thereby attain nonvolatile storage of data. Transition of the polarized state of a ferroelectric exhibits a hysteresis property, in which residual polarization remains in the ferroelectric even after the applied voltage becomes zero. Using this nature, nonvolatile storage of data is performed.

Japanese Laid-Open Patent Publication No. 6-243690 discloses a conventional ferroelectric random access memory (FeRAM) using a ferroelectric and a read/write technique for the same. FIG. 14 is a view showing a configuration of a conventional semiconductor memory device, and FIG. 15 is a timing chart showing the operation of the conventional semiconductor memory device.

In the prior art device described above, the cell plate voltage VPL is VDD/2 and the voltage amplitude of data lines DLfi and DBfi is VDD-0V. Therefore, the write voltage for memory cells MC is VDD/2, which is lower than the power supply voltage. This shortage of the write voltage causes such problems that memory characteristics may degrade with reduction in write polarization amount and speedup may be blocked with increase in write time. If the voltages VDD and VPL are raised to solve these problems, another problem that the device area significantly increases will arise because transistors having a withstand voltage higher than VDD must be used for sense amplifiers and the like.

### SUMMARY OF THE INVENTION

An object of the present invention is providing a semiconductor memory device in which the write voltage for memory cells is enhanced while increase in area is suppressed.

The semiconductor memory device of the present invention includes: a memory cell array composed of a plurality of memory cells arranged in a matrix, each of the memory cells including a capacitor having a plate electrode connected to a common cell plate and a storage electrode and a transistor provided between the storage electrode of the capacitor and a bit line, a gate of the transistor being connected to a word line; a first amplifier for amplifying potentials of an I/O line pair to a first voltage and a second voltage higher than the first voltage; a second amplifier for amplifying potentials of a bit line pair to the first voltage and a third voltage higher than the second voltage; and a switch element for switching a connection relationship between the I/O line pair and the bit line pair among a connected state in which the lines are electrically connected, a disconnected state in which the lines are electrically disconnected, and a transmission limited state in which the lines are electrically connected but the potential transmitted is limited, wherein the voltage of the cell plate is set at a voltage higher than the first voltage and lower than the third voltage.

According to the present invention, provided are the second amplifier for amplifying the potentials of the bit line pair to the first voltage and the third voltage, and the switch element for switching the connection relationship between the bit lines and the I/O lines among the connected state, the disconnected state and the transmission limited state. With this configuration, when the switch element switches to the transmission limited state, the voltage of the bit lines can be amplified to the third voltage that is higher than the second voltage by the second amplifier. Therefore, assuming that the second voltage is the power supply voltage VDD, by setting the third voltage at VDD2 (voltage twice as high as VDD) and the cell plate voltage at VDD, the write voltage for memory cells can be VDD. In other words, the write voltage for memory cells can be enhanced compared with the conventional case. Moreover, the first amplifier can be composed of transistors having a withstand voltage up to VDD, and only the second amplifier and the switch element include components requiring a withstand voltage higher than VDD. Thus, with no significant increase required in circuit area, the area of the semiconductor memory device can be kept small.

According to the semiconductor memory device of the present invention, the write voltage for memory cells can be enhanced and thus high-speed operation and improvement in memory characteristics can be attained with addition of the smallest number of components.

### BRIEF DESCRIPTION OF THE DRAWINGS

FIG. 1 is a block diagram of semiconductor memory devices of the embodiments of the present invention.

FIG. 2 is a block diagram of a memory cell.

FIG. 3 is a block diagram of a first amplifier in Embodiments 1, 2, 3 and 4 of the present invention.

FIG. 4 is a block diagram of a switch element in Embodiments 1, 4 and 5 of the present invention.

FIG. 5 is a block diagram of a second amplifier in the embodiments of the present invention.

FIG. 6 is a timing chart showing the operation in Embodiment 1 of the present invention.

FIG. 7 is a block diagram of a switch element in Embodiment 2 of the present invention.

FIG. 8 is a timing chart showing the operation in Embodiment 2 of the present invention.

FIG. 9 is a block diagram of a switch element in Embodiment 3 of the present invention.

FIG. 10 is a timing chart showing the operation in Embodiment 3 of the present invention.

FIG. 11 is a timing chart showing the operation in Embodiment 4 of the present invention.

FIG. 12 is a block diagram of a first amplifier in Embodiment 5 of the present invention.

FIG. 13 is a timing chart showing the operation in Embodiment 5 of the present invention.

FIG. 14 is a block diagram of a conventional semiconductor memory device.

FIG. 15 is a timing chart showing the operation of the conventional semiconductor memory device.

### DESCRIPTION OF THE PREFERRED EMBODIMENTS

Hereinafter, preferred embodiments of the present invention will be described with reference to the accompanying drawings.

### Embodiment 1

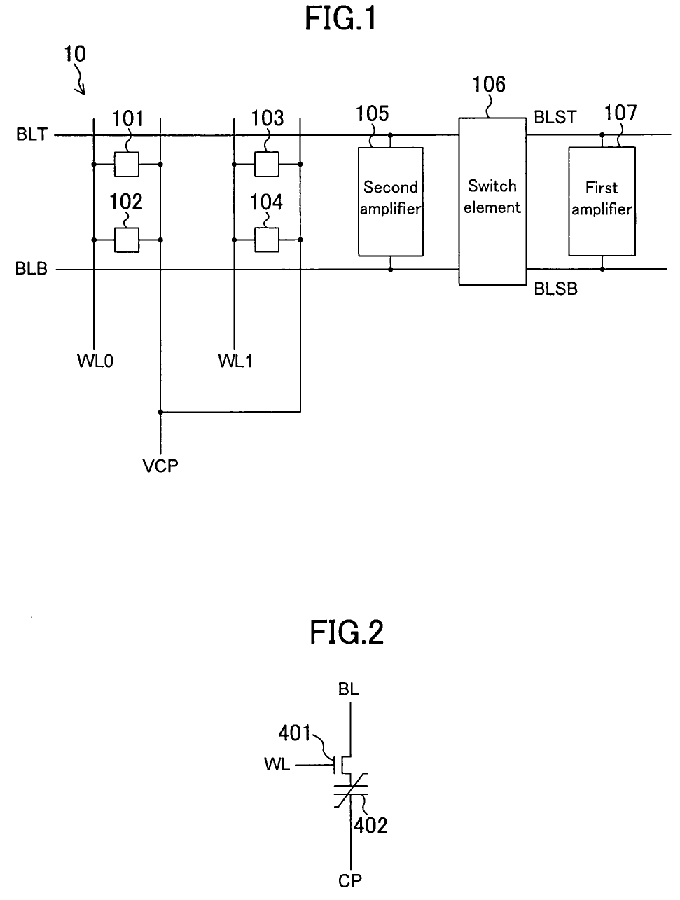

FIG. 1 is a view showing a configuration of a semiconductor memory device of Embodiment 1 of the present invention. Referring to FIG. 1, memory cells 101, 102, 103 and 104 are arranged in a matrix to constitute a memory cell array 10. FIG. 2 is a view showing a configuration of a memory cell, which includes an NMOS transistor 401 and a ferroelectric capacitor 402. The ferroelectric capacitor 402 has a plate electrode connected to a common cell plate CP and a storage electrode, with a ferroelectric film as the insulating film provided therebetween. The NMOS transistor 401 is placed between the storage electrode of the ferroelectric capacitor 402 and a bit line BL, and the gate thereof is connected to a word line WL. A cell plate potential VCP is applied to the cell plate CP.

Referring back to FIG. 1, the semiconductor memory device also includes: a first amplifier 107 for amplifying the potentials of an input/output (I/O) line pair BLST and BLSB to VSS as the first voltage and VDD as the second voltage higher than the first voltage; a second amplifier 105 for amplifying the potentials of a bit line pair BLT and BLB to VSS and VDD2 as the third voltage higher than VDD; and a switch element 106 having a function of switching the connection relationship between the I/O line pair BLST and BLSB and the bit line pair BLT and BLB.

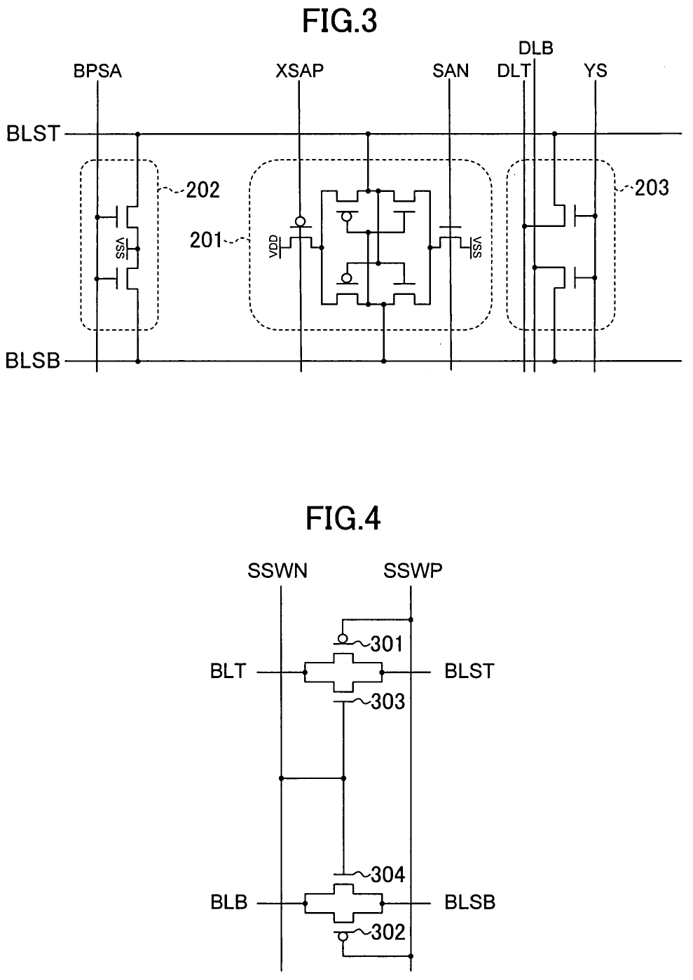

FIG. 3 is a view showing a configuration of the first amplifier 107, in which the reference numeral 201 denotes a cross-coupled CMOS amplifier, 202 denotes transistors for discharge to VSS, and 203 denotes transistors for transferring data on the I/O lines BLST and BLSB to a data line pair DLT and DLB.

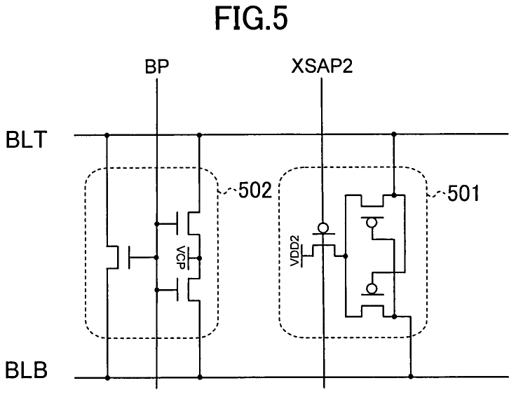

FIG. 4 is a view showing a configuration of the switch element 106, which includes PMOS transistors 301 and 302 and NMOS transistors 303 and 304. The PMOS transistor 301 and the NMOS transistor 303 are connected in parallel between the bit line BLT and the I/O line BLST, and the PMOS transistor 302 and the NMOS transistor 304 are connected in parallel between the bit line BLB and the I/O line BLSB. With signals SSWP and SSWN, the connection relationship between the I/O line pair BLST and BLSB and the bit line pair BLT and BLB is set at any one of a connected state in which the lines are electrically connected, a disconnected state in which the lines are electrically disconnected, and a transmission limited state in which the lines are electrically connected but the potential transmitted is limited. When both the PMOS transistor 301, 302 and the NMOS transistor 303, 304 are ON, the connected state is given. When both the transistors are OFF, the disconnected state is given. When only the NMOS transistor 303, 304 is ON, the transmission limited state is given.

FIG. 5 is a view showing a configuration of the second amplifier 105, in which the reference numeral 501 denotes a cross-coupled PMOS amplifier, and 502 denotes transistors for precharging the bit line pair BLT and BLB to VCP (VDD level) and equalization. In place of the cross-coupled PMOS amplifier 501, a cross-coupled CMOS amplifier may be provided.

The thickness of a gate oxide film is preferably different between the transistors constituting the first amplifier 107 and the transistors constituting the second amplifier 105. Alternatively, the source-drain breakdown voltage is preferably different between the transistors constituting the first amplifier 107 and the transistors constituting the second amplifier 105.

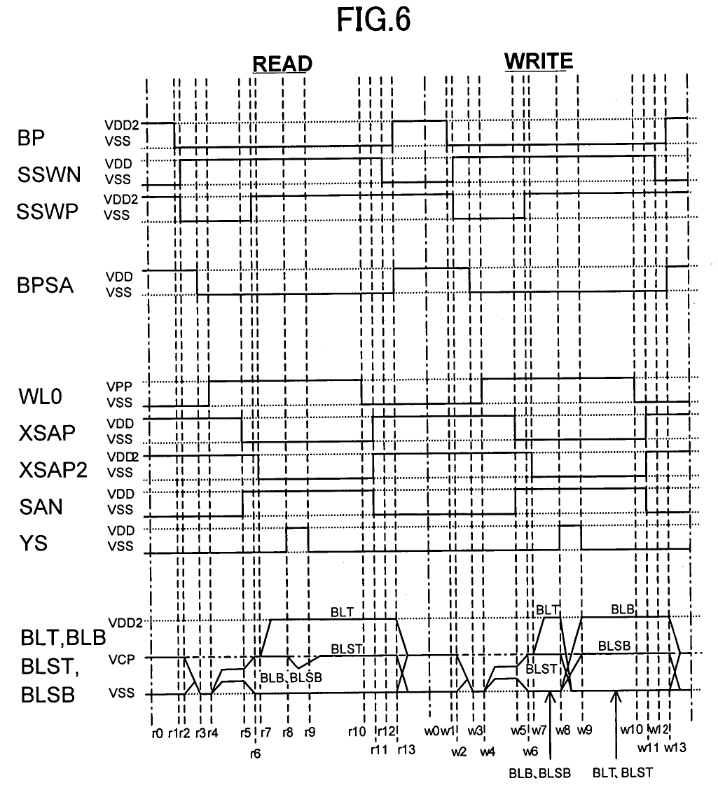

FIG. 6 is a timing chart showing the operation of the semiconductor memory device of this embodiment.

First, read operation will be described. At time r1, a signal BP becomes VSS level, terminating precharge of the bit lines BLT and BLB to VCP (VDD level) and equalization. At time r2, when the signal SSWN becomes VDD level while the signal SSWP becomes VSS level, the switch element 106 switches from the disconnected state to the connected state, allowing the bit lines BLT and BLB to be discharged to VSS by the first amplifier 107. At time r3, a signal BPSA becomes VSS level terminating the discharge of the bit lines BLT and BLB.

At time r4, a word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time r5, a signal SAN becomes VDD level while a signal XSAP becomes VSS level, to allow the voltages of the bit lines BLT and BLB and the I/O lines BLST and BLSB to be amplified to VDD and VSS. At time r6, the signal SSWP becomes VDD2 (VDD×2) level, allowing the switch element 106 to switch from the connected state to the transmission limited state. At time r7, a signal XSAP2 becomes VSS level, to allow the voltages of the bit lines BLT and BLB to be amplified to VDD2 and VSS by the second amplifier 105.

At time r8, a signal YS becomes VDD level, electrically connecting the I/O lines BLST and BLSB with the data lines DLT and DLB and thus allowing data to be transferred to the data lines DLT and DLB. At time r9, the signal YS becomes VSS level, terminating the data transfer to the data lines DLT and DLB. At time r10, the word line WL0 becomes VSS level. At time r11, the signal SAN becomes VSS level, the signal XSAP becomes VDD level, and the signal XSAP2 becomes VDD2 level, so that the first amplifier 107 and the second amplifier 105 stop the amplification. At time r12, the signal SSWN becomes VSS level, allowing the switch element 106 to switch from the transmission limited state to the disconnected state, to electrically disconnect the bit lines BLT and BLB from the I/O lines BLST and BLSB. At time r13, the signal BPSA becomes VDD level to discharge the I/O lines BLST and BLSB to VSS level, and the signal BP becomes VDD2 level to precharge the bit lines BLT and BLB to VCP (VDD level). The read operation is thus completed.

Next, write operation will be described. At time w1, the signal BP becomes VSS level terminating precharge of the bit lines BLT and BLB to VCP (VDD level) and equalization. At time w2, when the signal SSWN becomes VDD level while the signal SSWP becomes VSS level, the switch element 106 switches from the disconnected state to the connected state, allowing the bit lines BLT and BLB to be discharged to VSS by the first amplifier 107. At time w3, the signal BPSA becomes VSS level terminating the discharge of the bit lines BLT and BLB.

At time w4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time w5, the signal SAN becomes VDD level while the signal XSAP becomes VSS level, to allow the voltages of the bit lines BLT and BLB and the I/O lines BLST and BLSB to be amplified to VDD and VSS. At time w6, the signal SSWP becomes VDD2 (VDD×2) level, allowing the switch element 106 to switch from the connected state to the transmission limited state. At time w7, the signal XSAP2 becomes VSS level, to allow the voltages of the bit lines BLT and BLB to be amplified to VDD2 and VSS by the second amplifier 105.

At time w8, the signal YS becomes VDD level, allowing data on the data lines DLT and DLB to be transferred to the I/O lines BLST and BLSB and the bit lines BLT and BLB. The voltages of the bit lines BLT and BLB are then VDD2 and VSS depending on the data, to allow voltages “VDD” and “−VDD” to be respectively applied to the ferroelectric capacitors in relevant memory cells. At time w9, the signal YS becomes VSS level, terminating the data transfer from the data lines DLT and DLB to the I/O lines BLST and BLSB and the bit lines BLT and BLB. At time w10, the word line WL0 becomes VSS level. At time w11, the signal SAN becomes VSS level, the signal XSAP becomes VDD level, and the signal XSAP2 becomes VDD2 level, so that the first amplifier 107 and the second amplifier 105 stop the amplification. At time w12, the signal SSWN becomes VSS level, allowing the switch element 106 to switch from the transmission limited state to the disconnected state, to electrically disconnect the bit lines BLT and BLB from the I/O lines BLST and BLSB. At time w13, the signal BPSA becomes VDD level to discharge the I/O lines BLST and BLSB to VSS level, and the signal BP becomes VDD2 level to precharge the bit lines BLT and BLB to VCP (VDD level). The write operation is thus completed.

As described above, in this embodiment, the potential difference between the bit line pair BLT and BLB can be amplified to the third voltage higher than VDD by providing the second amplifier 105 for amplifying the potentials of the bit line pair BLT and BLB to VDD2 and VSS and the switch element 106 for switching the connection relationship between the bit lines BLT and BLB and the I/O lines BLST and BLSB among the connected state, the disconnected state and the transmission limited state. In this embodiment, the first amplifier 107 can be configured of transistors having a withstand voltage up to VDD, and only the second amplifier 105 and the switch element 106 include components required to have a withstand voltage higher than VDD. The area is therefore kept small. By setting the third voltage at VDD2 (twice as high as the voltage VDD) and the cell plate voltage at the power supply voltage VDD, the write voltage for memory cells can be VDD.

### Embodiment 2

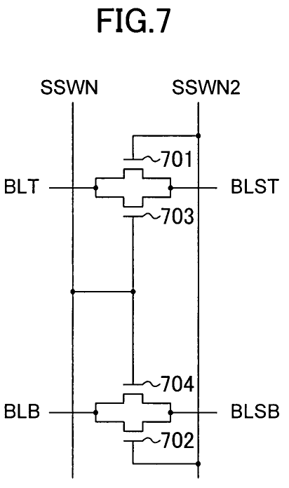

The semiconductor memory device of Embodiment 2 of the present invention is configured as shown in FIG. 1, but the configuration of the switch element 106 is different from that in Embodiment 1. FIG. 7 is a view showing the configuration of the switch element in this embodiment, which includes NMOS transistors 701, 702, 703 and 704. The NMOS transistors 701 and 703 are connected in parallel between the bit line BLT and the I/O line BLST, and the NMOS transistors 702 and 704 are connected in parallel between the bit line BLB and the I/O line BLSB. With signals SSWN and SSWN2, the connection relationship between the I/O line pair BLST and BLSB and the bit line pair BLT and BLB is set at any one of the electrically connected state, the electrically disconnected state and the transmission limited state in which the lines are electrically connected but the potential transmitted is limited. When both the NMOS transistor 701, 702 and the NMOS transistor 703, 704 are ON, the connected state is given. When both transistors are OFF, the disconnected state is given. When only the NMOS transistor 703, 704 is ON, the transmission limited state is given. By configuring the switch element 106 as shown in FIG. 7, the area can be reduced.

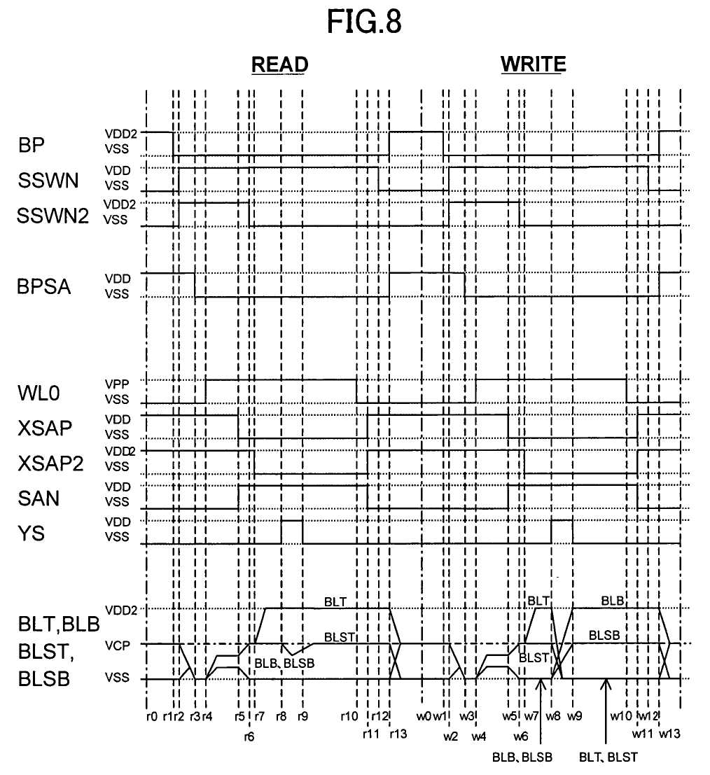

FIG. 8 is a timing chart showing the operation of the semiconductor memory device of this embodiment.

First, read operation will be described. At time r1, the signal BP becomes VSS level, terminating precharge of the bit lines BLT and BLB to VCP (VDD level) and equalization. At time r2, when the signal SSWN becomes VDD level while the signal SSWN2 becomes VDD2 (VDD×2) level, the switch element 106 switches from the disconnected state to the connected state, allowing the bit lines BLT and BLB to be discharged to VSS by the first amplifier 107. At time r3, the signal BPSA becomes VSS level terminating the discharge of the bit lines BLT and BLB.

At time r4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time r5, the signal SAN becomes VDD level while the signal XSAP becomes VSS level, to allow the voltages of the bit lines BLT and BLB and the I/O lines BLST and BLSB to be amplified to VDD and VSS. At time r6, the signal SSWN2 becomes VSS level, allowing the switch element 106 to switch from the connected state to the transmission limited state. At time r7, the signal XSAP2 becomes VSS level, to allow the voltages of the bit lines BLT and BLB to be amplified to VDD2 and VSS by the second amplifier 105.

At time r8, the signal YS becomes VDD level, electrically connecting the I/O lines BLST and BLSB with the data lines DLT and DLB and thus allowing data to be transferred to the data lines DLT and DLB. At time r9, the signal YS becomes VSS level, terminating the data transfer to the data lines DLT and DLB. At time r10, the word line WL0 becomes VSS level. At time r11, the signal SAN becomes VSS level, the signal XSAP becomes VDD level, and the signal XSAP2 becomes VDD2 level, so that the first amplifier 107 and the second amplifier 105 stop the amplification. At time r12, the signal SSWN becomes VSS level, allowing the switch element 106 to switch from the transmission limited state to the disconnected state, to electrically disconnect the bit lines BLT and BLB from the I/O lines BLST and BLSB. At time r13, the signal BPSA becomes VDD level to discharge the I/O lines BLST and BLSB to VSS level, and the signal BP becomes VDD2 level to precharge the bit lines BLT and BLB to VCP (VDD level). The read operation is thus completed.

Next, write operation will be described. At time w1, the signal BP becomes VSS level terminating precharge of the bit lines BLT and BLB to VCP (VDD level) and equalization. At time w2, when the signal SSWN becomes VDD level while the signal SSWN2 becomes VDD2 (VDD×2) level, the switch element 106 switches from the disconnected state to the connected state, allowing the bit lines BLT and BLB to be discharged to VSS by the first amplifier 107. At time w3, the signal BPSA becomes VSS level terminating the discharge of the bit lines BLT and BLB.

At time w4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time w5, the signal SAN becomes VDD level while the signal XSAP becomes VSS level, to allow the voltages of the bit lines BLT and BLB and the I/O lines BLST and BLSB to be amplified to VDD and VSS. At time w6, the signal SSWN2 becomes VSS level, allowing the switch element 106 to switch from the connected state to the transmission limited state. At time w7, the signal XSAP2 becomes VSS level, to allow the voltages of the bit lines BLT and BLB to be amplified to VDD2 and VSS by the second amplifier 105.

At time w8, the signal YS becomes VDD level, allowing data on the data lines DLT and DLB to be transferred to the I/O lines BLST and BLSB and the bit lines BLT and BLB. The voltages of the bit lines BLT and BLB are then VDD2 and VSS depending on the data, to allow voltages “VDD” and “−VDD” to be respectively applied to the ferroelectric capacitors in relevant memory cells. At time w9, the signal YS becomes VSS level, terminating the data transfer from the data lines DLT and DLB to the I/O lines BLST and BLSB and the bit lines BLT and BLB. At time w10, the word line WL0 becomes VSS level. At time will, the signal SAN becomes VSS level, the signal XSAP becomes VDD level, and the signal XSAP2 becomes VDD2 level, so that the first amplifier 107 and the second amplifier 105 stop the amplification. At time w12, the signal SSWN becomes VSS level, allowing the switch element 106 to switch from the transmission limited state to the disconnected state, to electrically disconnect the bit lines BLT and BLB from the I/O lines BLST and BLSB. At time w13, the signal BPSA becomes VDD level to discharge the I/O lines BLST and BLSB to VSS level, and the signal BP becomes VDD2 level to precharge the bit lines BLT and BLB to VCP (VDD level). The write operation is thus completed.

### Embodiment 3

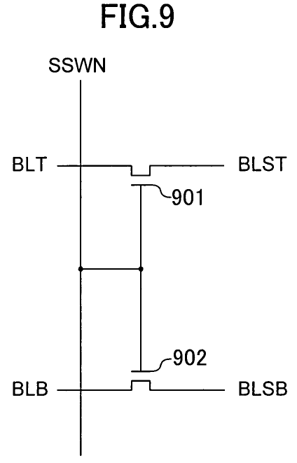

The semiconductor memory device of Embodiment 3 of the present invention is configured as shown in FIG. 1, but the configuration of the switch element 106 is different from that in Embodiment 1. FIG. 9 is a view showing the configuration of the switch element in this embodiment, which includes NMOS transistors 901 and 902. The NMOS transistor 901 is connected between the bit line BLT and the I/O line BLST, and the NMOS transistor 902 is connected between the bit line BLB and the I/O line BLSB. With the level of the signal SSWN, the connection relationship between the I/O line pair BLST and BLSB and the bit line pair BLT and BLB is set at any one of the electrically connected state, the electrically disconnected state and the transmission limited state in which the lines are electrically connected but the potential transmitted is limited. By configuring the switch element 106 as shown in FIG. 9, the area can further be reduced.

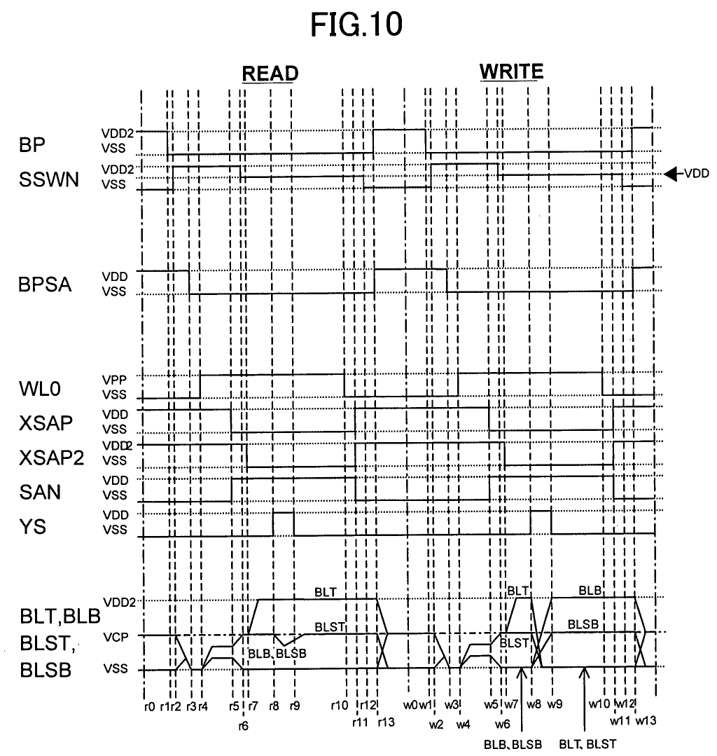

FIG. 10 is a timing chart showing the operation of the semiconductor memory device of this embodiment.

First, read operation will be described. At time r1, the signal BP becomes VSS level, terminating precharge of the bit lines BLT and BLB to VCP (VDD level) and equalization. At time r2, when the signal SSWN becomes VDD2 (VDD×2) level, the switch element 106 switches from the disconnected state to the connected state, allowing the bit lines BLT and BLB to be discharged to VSS by the first amplifier 107. At time r3, the signal BPSA becomes VSS level terminating the discharge of the bit lines BLT and BLB.

At time r4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time r5, the signal SAN becomes VDD level while the signal XSAP becomes VSS level, to allow the voltages of the bit lines BLT and BLB and the I/O lines BLST and BLSB to be amplified to VDD and VSS. At time r6, the signal SSWN becomes VDD level, allowing the switch element 106 to switch from the connected state to the transmission limited state. At time r7, the signal XSAP2 becomes VSS level, to allow the voltages of the bit lines BLT and BLB to be amplified to VDD2 and VSS by the second amplifier 105.

At time r8, the signal YS becomes VDD level, electrically connecting the I/O lines BLST and BLSB with the data lines DLT and DLB and thus allowing data to be transferred to the data lines DLT and DLB. At time r9, the signal YS becomes VSS level, terminating the data transfer to the data lines DLT and DLB. At time r10, the word line WL0 becomes VSS level. At time r11, the signal SAN becomes VSS level, the signal XSAP becomes VDD level, and the signal XSAP2 becomes VDD2 level, so that the first amplifier 107 and the second amplifier 105 stop the amplification. At time r12, the signal SSWN becomes VSS level, allowing the switch element 106 to switch from the transmission limited state to the disconnected state, to electrically disconnect the bit lines BLT and BLB from the I/O lines BLST and BLSB. At time r13, the signal BPSA becomes VDD level to discharge the I/O lines BLST and BLSB to VSS level, and the signal BP becomes VDD2 level to precharge the bit lines BLT and BLB to VCP (VDD level). The read operation is thus completed.

Next, write operation will be described. At time w1, the signal BP becomes VSS level terminating precharge of the bit lines BLT and BLB to VCP (VDD level) and equalization. At time w2, when the signal SSWN becomes VDD2 (VDD×2) level, the switch element 106 switches from the disconnected state to the connected state, allowing the bit lines BLT and BLB to be discharged to VSS by the first amplifier 107. At time w3, the signal BPSA becomes VSS level terminating the discharge of the bit lines BLT and BLB.

At time w4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time w5, the signal SAN becomes VDD level while the signal XSAP becomes VSS level, to allow the voltages of the bit lines BLT and BLB and the I/O lines BLST and BLSB to be amplified to VDD and VSS. At time w6, the signal SSWN becomes VDD level, allowing the switch element 106 to switch from the connected state to the transmission limited state. At time w7, the signal XSAP2 becomes VSS level, to allow the voltages of the bit lines BLT and BLB to be amplified to VDD2 and VSS by the second amplifier 105.

At time w8, the signal YS becomes VDD level, allowing data on the data lines DLT and DLB to be transferred to the I/O lines BLST and BLSB and the bit lines BLT and BLB. The voltages of the bit lines BLT and BLB are then VDD2 and VSS depending on the data, to allow voltages “VDD” and “−VDD” to be respectively applied to the ferroelectric capacitors in relevant memory cells. At time w9, the signal YS becomes VSS level, terminating the data transfer from the data lines DLT and DLB to the I/O lines BLST and BLSB and the bit lines BLT and BLB. At time w10, the word line WL0 becomes VSS level. At time will, the signal SAN becomes VSS level, the signal XSAP becomes VDD level, and the signal XSAP2 becomes VDD2 level, so that the first amplifier 107 and the second amplifier 105 stop the amplification. At time w12, the signal SSWN becomes VSS level, allowing the switch element 106 to switch from the transmission limited state to the disconnected state, to electrically disconnect the bit lines BLT and BLB from the I/O lines BLST and BLSB. At time w13, the signal BPSA becomes VDD level to discharge the I/O lines BLST and BLSB to VSS level, and the signal BP becomes VDD2 level to precharge the bit lines BLT and BLB to VCP (VDD level). The write operation is thus completed.

### Embodiment 4

The semiconductor memory device of Embodiment 4 of the present invention is configured as shown in FIG. 1, and the internal configurations of the components are the same as those in Embodiment 1, except that the timing at which the switch element 106 switches from the connected state to the transmission limited state comes before the startup of the first amplifier 107. By permitting this switching to the transmission limited state before the startup of the first amplifier 107, the voltage amplification in the first amplifier 107 can be sped up, and this speeds up the data transfer to the data lines.

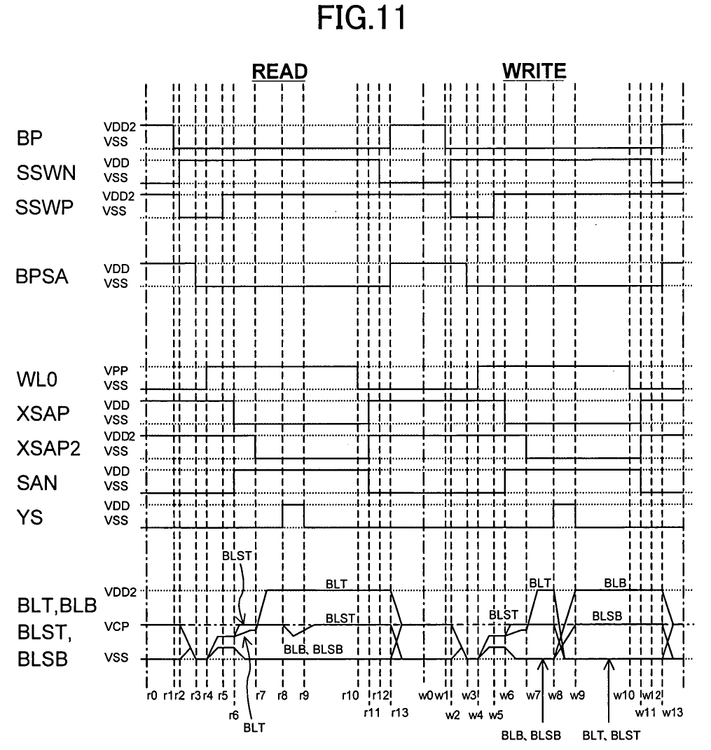

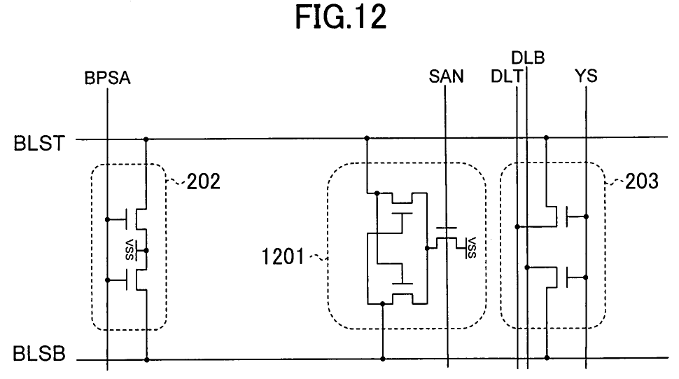

FIG. 11 is a timing chart showing the operation of the semiconductor memory device of this embodiment.

First, read operation will be described. At time r1, the signal BP becomes VSS level, terminating precharge of the bit lines BLT and BLB to VCP (VDD level) and equalization. At time r2, when the signal SSWN becomes VDD level while the signal SSWP becomes VSS level, the switch element 106 switches from the disconnected state to the connected state, allowing the bit lines BLT and BLB to be discharged to VSS by the first amplifier 107. At time r3, the signal BPSA becomes VSS level terminating the discharge of the bit lines BLT and BLB.

At time r4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time r5, the signal SSWP becomes VDD2 (VDD×2) level, allowing the switch element 106 to switch from the connected state to the transmission limited state. At time r6, the signal SAN becomes VDD level while the signal XSAP becomes VSS level, to allow the voltages of the bit lines BLT and BLB to be amplified to (VDD−Vt) and VSS and the voltages of the I/O lines BLST and BLSB to be amplified to VDD and VSS. At time r7, the signal XSAP2 becomes VSS level, to allow the voltages of the bit lines BLT and BLB to be amplified to VDD2 and VSS by the second amplifier 105.

At time r8, the signal YS becomes VDD level, electrically connecting the I/O lines BLST and BLSB with the data lines DLT and DLB and thus allowing data to be transferred to the data lines DLT and DLB. At time r9, the signal YS becomes VSS level, terminating the data transfer to the data lines DLT and DLB. At time r10, the word line WL0 becomes VSS level. At time r11, the signal SAN becomes VSS level, the signal XSAP becomes VDD level, and the signal XSAP2 becomes VDD2 level, so that the first amplifier 107 and the second amplifier 105 stop the amplification. At time r12, the signal SSWN becomes VSS level, allowing the switch element 106 to switch from the transmission limited state to the disconnected state, to electrically disconnect the bit lines BLT and BLB from the I/O lines BLST and BLSB. At time r13, the signal BPSA becomes VDD level to discharge the I/O lines BLST and BLSB to VSS level, and the signal BP becomes VDD2 level to precharge the bit lines BLT and BLB to VCP (VDD level). The read operation is thus completed.

Next, write operation will be described. At time w1, the signal BP becomes VSS level terminating precharge of the bit lines BLT and BLB to VCP (VDD level) and equalization. At time w2, when the signal SSWN becomes VDD level while the signal SSWP becomes VSS level, the switch element 106 switches from the disconnected state to the connected state, allowing the bit lines BLT and BLB to be discharged to VSS by the first amplifier 107. At time w3, the signal BPSA becomes VSS level terminating the discharge of the bit lines BLT and BLB.

At time w4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time w5, the signal SSWP becomes VDD2 (VDD×2) level, allowing the switch element 106 to switch from the connected state to the transmission limited state. At time w6, the signal SAN becomes VDD level while the signal XSAP becomes VSS level, to allow the voltages of the bit lines BLT and BLB to be amplified to (VDD−Vt) and VSS and the voltages of the I/O lines BLST and BLSB to be amplified to VDD to VSS. At time w7, the signal XSAP2 becomes VSS level, to allow the voltages of the bit lines BLT and BLB to be amplified to VDD2 to VSS by the second amplifier 105.

At time w8, the signal YS becomes VDD level, allowing data on the data lines DLT and DLB to be transferred to the I/O lines BLST and BLSB and the bit lines BLT and BLB. The voltages of the bit lines BLT and BLB are then VDD2 and VSS depending on the data, to allow voltages “VDD” and “−VDD” to be respectively applied to the ferroelectric capacitors in relevant memory cells. At time w9, the signal YS becomes VSS level, terminating the data transfer from the data lines DLT and DLB to the I/O lines BLST and BLSB and the bit lines BLT and BLB. At time w10, the word line WL0 becomes VSS level. At time w11, the signal SAN becomes VSS level, the signal XSAP becomes VDD level, and the signal XSAP2 becomes VDD2 level, so that the first amplifier 107 and the second amplifier 105 stop the amplification. At time w12, the signal SSWN becomes VSS level, allowing the switch element 106 to switch from the transmission limited state to the disconnected state, to electrically disconnect the bit lines BLT and BLB from the I/O lines BLST and BLSB. At time w13, the signal BPSA becomes VDD level to discharge the I/O lines BLST and BLSB to VSS level, and the signal BP becomes VDD2 level to precharge the bit lines BLT and BLB to VCP (VDD level). The write operation is thus completed.

### Embodiment 5

The semiconductor memory device of Embodiment 5 of the present invention is configured as shown in FIG. 1, but the configuration of the first amplifier 107 is different from that in Embodiment 1. FIG. 12 is a view showing the configuration of the first amplifier 107 in this embodiment, in which the same components as those in FIG. 3 are denoted by the same reference numerals, and the description thereof is omitted here. In FIG. 12, a cross-coupled NMOS amplifier 1201 is provided in place of the cross-coupled CMOS amplifier 201. With the first amplifier composed of only NMOS transistors, a further smaller area can be attained than in Embodiment 1.

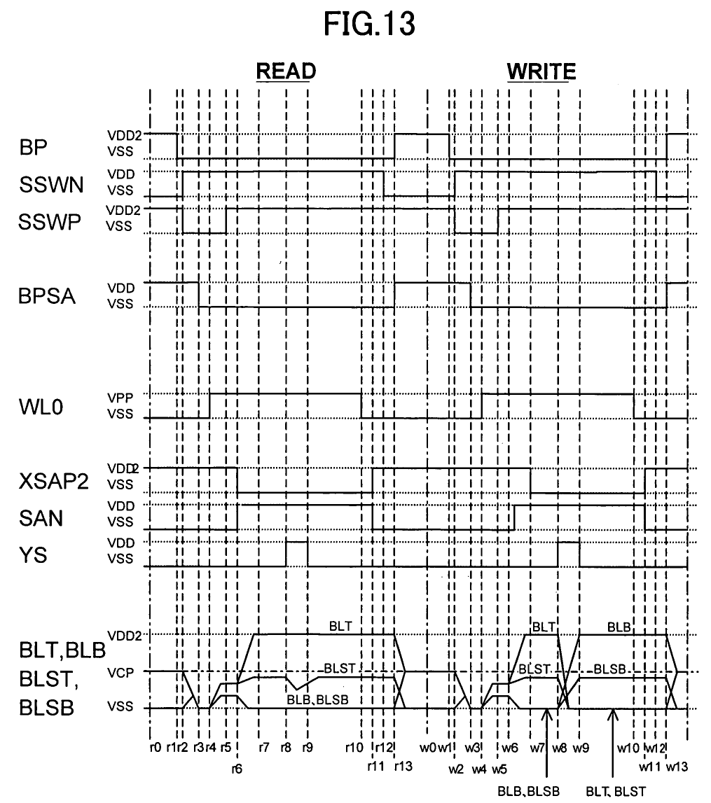

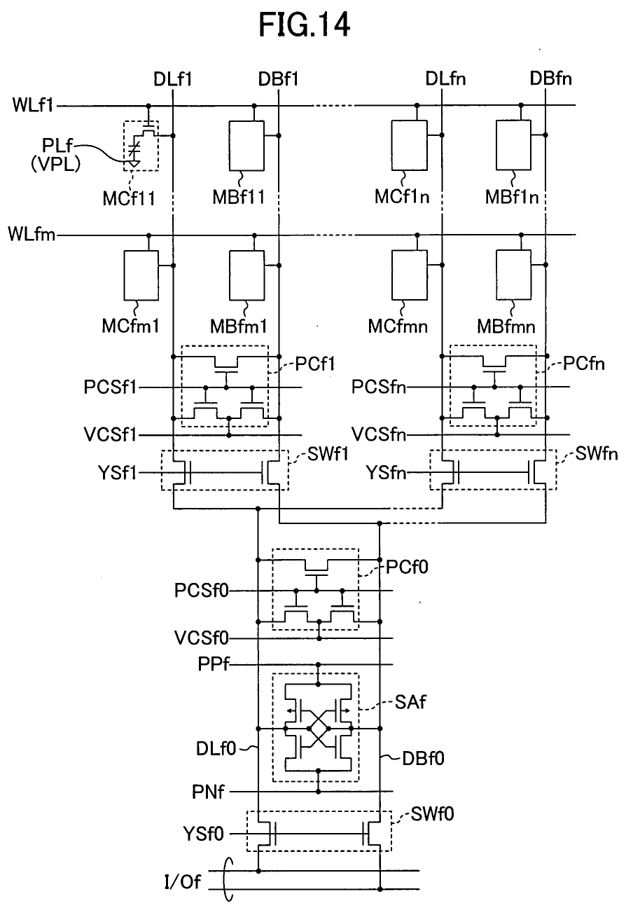

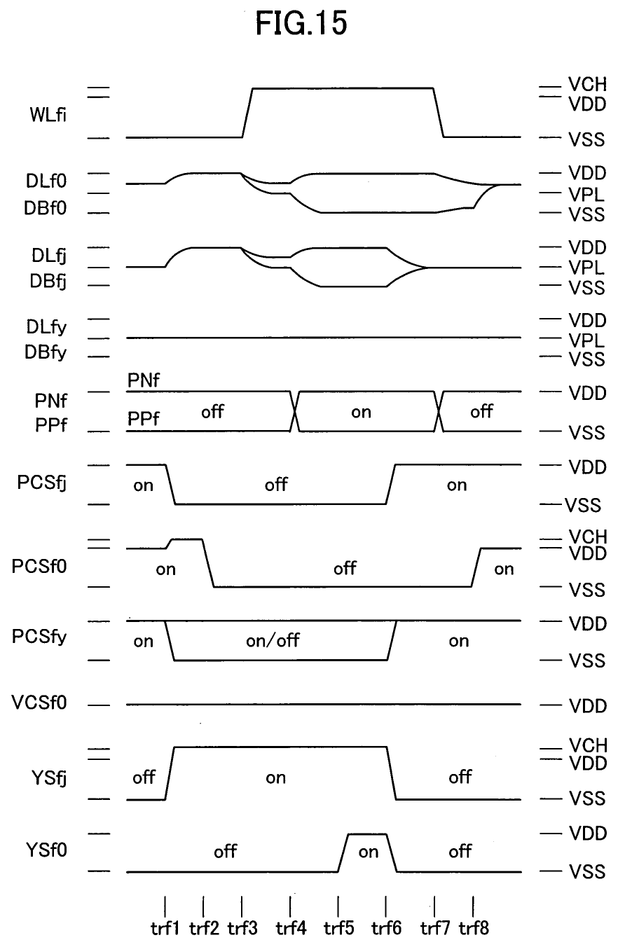

FIG. 13 is a timing chart showing the operation of the semiconductor memory device of this embodiment.

First, read operation will be described. At time r1, the signal BP becomes VSS level, terminating precharge of the bit lines BLT and BLB to VCP (VDD level) and equalization. At time r2, when the signal SSWN becomes VDD level while the signal SSWP becomes VSS level, the switch element 106 switches from the disconnected state to the connected state, allowing the bit lines BLT and BLB to be discharged to VSS by the first amplifier 107. At time r3, the signal BPSA becomes VSS level terminating the discharge of the bit lines BLT and BLB.

At time r4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time r5, the signal SSWP becomes VDD2 (VDD×2) level, allowing the switch element 106 to switch from the connected state to the transmission limited state. At time r6, the signal SAN becomes VDD level while the signal XSAP2 becomes VSS level, to allow the voltages of the bit lines BLT and BLB to be amplified to VDD2 and VSS and the voltages of the I/O lines BLST and BLSB to be amplified to (VDD−Vt) and VSS.

At time r8, the signal YS becomes VDD level, electrically connecting the I/O lines BLST and BLSB with the data lines DLT and DLB and thus allowing data to be transferred to the data lines DLT and DLB. At time r9, the signal YS becomes VSS level, terminating the data transfer to the data lines DLT and DLB. At time r10, the word line WL0 becomes VSS level. At time r11, the signal SAN becomes VSS level, and the signal XSAP2 becomes VDD2 level, so that the first amplifier 107 and the second amplifier 105 stop the amplification. At time r12, the signal SSWN becomes VSS level, allowing the switch element 106 to switch from the transmission limited state to the disconnected state, to electrically disconnect the bit lines BLT and BLB from the I/O lines BLST and BLSB. At time r13, the signal BPSA becomes VDD level to discharge the I/O lines BLST and BLSB to VSS level, and the signal BP becomes VDD2 level to precharge the bit lines BLT and BLB to VCP (VDD level). The read operation is thus completed.

Next, write operation will be described. At time w1, the signal BP becomes VSS level terminating precharge of the bit lines BLT and BLB to VCP (VDD level) and equalization. At time w2, when the signal SSWN becomes VDD level while the signal SSWP becomes VSS level, the switch element 106 switches from the disconnected state to the connected state, allowing the bit lines BLT and BLB to be discharged to VSS by the first amplifier 107. At time w3, the signal BPSA becomes VSS level terminating the discharge of the bit lines BLT and BLB.

At time w4, the word line WL0 becomes VPP level (VDD×2+Vt), allowing the voltage VDD to be applied across the terminals of the ferroelectric capacitor in each of relevant memory cells, and thereafter a potential difference to arise between the bit lines BLT and BLB. At time w5, the signal SSWP becomes VDD2 (VDD×2) level, allowing the switch element 106 to switch from the connected state to the transmission limited state. At time w6, the signal SAN becomes VDD level while the signal XSAP2 becomes VSS level, to allow the voltages of the bit lines BLT and BLB to be amplified to VDD2 and VSS and the voltages of the I/O lines BLST and BLSB to be amplified to (VDD−Vt) and VSS.

At time w8, the signal YS becomes VDD level, allowing data on the data lines DLT and DLB to be transferred to the I/O lines BLST and BLSB and the bit lines BLT and BLB. The voltages of the bit lines BLT and BLB are then VDD2 and VSS depending on the data, to allow voltages “VDD” and “−VDD” to be respectively applied to the ferroelectric capacitors in relevant memory cells. At time w9, the signal YS becomes VSS level, terminating the data transfer from the data lines DLT and DLB to the I/O lines BLST and BLSB and the bit lines BLT and BLB. At time w10, the word line WL0 becomes VSS level. At time w11, the signal SAN becomes VSS level, and the signal XSAP2 becomes VDD2 level, so that the first amplifier 107 and the second amplifier 105 stop the amplification. At time w12, the signal SSWN becomes VSS level, allowing the switch element 106 to switch from the transmission limited state to the disconnected state, to electrically disconnect the bit lines BLT and BLB from the I/O lines BLST and BLSB. At time w13, the signal BPSA becomes VDD level to discharge the I/O lines BLST and BLSB to VSS level, and the signal BP becomes VDD2 level to precharge the bit lines BLT and BLB to VCP (VDD level). The write operation is thus completed.

Although ferroelectric semiconductor memory devices using ferroelectric capacitors as information memory elements were exemplified in the embodiments described above, the present invention is not limited to such ferroelectric semiconductor memory devices.

In the embodiments described above, the voltages were set so that VDD=power supply voltage, VCP=power supply voltage, VDD2=VDD×2, VPP=VDD×2+Vt, and VSS=ground voltage. However, the present invention is applicable as long as VDD2 is a voltage higher than the power supply voltage, VPP is a voltage higher than VDD2, and VCP is a voltage somewhere between VDD2 and VSS.

According to the present invention, since data can be written in/read from memory cells with high voltage while the area is kept small, the memory characteristics of the semiconductor memory device can be enhanced.

While the present invention has been described in preferred embodiments, it will be apparent to those skilled in the art that the disclosed invention may be modified in numerous ways and may assume many embodiments other than that specifically set out and described above. Accordingly, it is intended by the appended claims to cover all modifications of the invention which fall within the true spirit and scope of the invention.

What is claimed is:

1. A semiconductor memory device comprising:
a memory cell array composed of a plurality of memory cells arranged in a matrix, each of the memory cells including a capacitor having a plate electrode connected to a common cell plate and a storage electrode and a transistor provided between the storage electrode of the capacitor and a bit line, a gate of the transistor being connected to a word line;
a first amplifier for amplifying potentials of an I/O line pair to a first voltage and a second voltage higher than the first voltage;
a second amplifier for amplifying potentials of a bit line pair to the first voltage and a third voltage higher than the second voltage; and
a switch element for switching a connection relationship between the I/O line pair and the bit line pair among a connected state in which the lines are electrically connected, a disconnected state in which the lines are electrically disconnected, and a transmission limited state in which the lines are electrically connected but the potential transmitted is limited,
wherein the voltage of the cell plate is set at a voltage higher than the first voltage and lower than the third voltage.

2. The device of claim 1, wherein the switch element includes a PMOS transistor and an NMOS transistor connected in parallel, provided each between one of the I/O line pair and one of the bit line pair and between the other of the I/O line pair and the other of the bit line pair.

3. The device of claim 1, wherein the switch element includes two NMOS transistors connected in parallel, provided each between one of the I/O line pair and one of the bit line pair and between the other of the I/O line pair and the other of the bit line pair.

4. The device of claim 1, wherein the switch element includes an NMOS transistor provided each between one of the I/O line pair and one of the bit line pair and between the other of the I/O line pair and the other of the bit line pair, and
switches among the connected state, the disconnected state and the transmission limited state according to the level of a gate voltage of the NMOS transistor.

5. The device of claim 1, wherein in read operation and write operation, the switch element switches from the disconnected state to the connected state,
the first amplifier performs amplification,
the switch element switches from the connected state to the transmission limited state, and
the second amplifier performs amplification.

6. The device of claim 1, wherein in read operation and write operation, the switch element switches from the disconnected state to the connected state,
the switch element switches from the connected state to the transmission limited state,
the first amplifier performs amplification, and
the second amplifier performs amplification.

7. The device of claim 1, wherein the first amplifier includes a cross-coupled CMOS amplifier, and
the second amplifier includes a cross-coupled CMOS amplifier.

8. The device of claim 1, wherein the first amplifier includes a cross-coupled CMOS amplifier, and
the second amplifier includes a cross-coupled PMOS amplifier.

9. The device of claim 1, wherein the first amplifier includes a cross-coupled NMOS amplifier, and
the second amplifier includes a cross-coupled PMOS amplifier.

10. The device of claim 1, wherein transistors constituting the first amplifier and transistors constituting the second amplifier are different in gate oxide film thickness.

11. The device of claim 1, wherein transistors constituting the first amplifier and transistors constituting the second amplifier are different in source-drain breakdown voltage.

12. The device of claim 1, wherein the capacitor is a ferroelectric capacitor having a ferroelectric film provided as an insulating film.
